(19) United States
(12) Patent Application Publication
(10) Pub. No.: US 2026/0045294 A1
(43) Pub. Date: Feb. 12, 2026

(54) ROW DECODER CIRCUIT

(71) Applicant: Winbond Electronics Corp., Taichung City (TW)

(72) Inventor: Shu-Meng Yang, Hualien (TW)

(73) Assignee: Winbond Electronics Corp., Taichung City (TW)

(21) Appl. No.: 19/278,800

(22) Filed: Jul. 24, 2025

Related U.S. Application Data
(60) Provisional application No. 63/681,889, filed on Aug. 12, 2024.

(30) Foreign Application Priority Data
Dec. 9, 2024 (TW) 113147751

(51) Int. Cl. G11C 11/408

(52) U.S. Cl. CPC G11C 11/4087

(57) ABSTRACT

A row decoder circuit adapted to a memory device is provided. The row decoder circuit includes a pre-decoder, multiple decoders, and a mapping control circuit. The pre-decoder is configured to receive row address information and decode the row address information to provide a row select signal group. The decoders sequentially correspond to multiple row address ranges. The mapping control circuit is configured to obtain a selected raw address range according to the row select signal group, and cause the decoder whose corresponding row address range is the same as the selected row address range to output a word line signal. The mapping control circuit reorders the row address ranges corresponding to the decoders according to verification data.

### CROSS-REFERENCE TO RELATED APPLICATION

This application claims the priority benefit of U.S. provisional application Ser. No. 63/681,889, filed on Aug. 12, 2024 and Taiwan application no. 113147751, filed on Dec. 9, 2024. The entirety of the above-mentioned patent application is hereby incorporated by reference herein and made a part of this specification.

### BACKGROUND

### Technical Field

The disclosure relates to a decoder circuit, and more particularly, to a row decoder circuit.

### Description of Related Art

With the development of memory process technology, memory density increases, a die area increases, and a damage rate of each of the dies also increases. It is almost impossible for all memory cells or memory blocks inside a memory product to be 100% damage-free. To this end, in the conventional technology, row/col redundancy techniques and ECC techniques are mainly used to repair the damaged memory cells. However, repair capabilities of the above technologies are limited, and some memory devices (chips) that are more damaged may not be completely repaired. Since a position of damage is random, the partially damaged memory devices may not be shipped as normal products, which reduces a product yield.

### SUMMARY

The disclosure provides a row decoder circuit that may cause a partially damaged memory device to have availability.

A row decoder circuit in the disclosure is adapted to a memory device, including a pre-decoder, multiple decoders, and a mapping control circuit. The pre-decoder is configured to receive row address information and decode the row address information to provide a row select signal group. The decoders sequentially correspond to multiple row address ranges. The mapping control circuit is coupled to the pre-decoder and the decoders, and is configured to obtain a selected row address range according to the row select signal group and cause the decoder having the corresponding row address range that is the same as the selected row address range to output a word line signal. The mapping control circuit reorders the row address ranges corresponding to the decoders according to verification data.

Based on the above, by reordering the row address ranges corresponding to the decoders, the row decoder circuit in the disclosure may skip the damaged bad memory blocks during mapping and allow the memory device to be used normally. In this way, the partially damaged memory device may still have the availability, which may also increase a product yield and ease of use.

In order for the aforementioned features and advantages of the disclosure to be more comprehensible, embodiments accompanied with drawings are described in detail below.

### BRIEF DESCRIPTION OF THE DRAWINGS

FIG. 1 is a block diagram of a row decoder circuit according to an embodiment.

FIG. 2 is a schematic diagram of an operation of a row decoder circuit according to an embodiment.

FIGS. 3A to 3C are schematic circuit diagrams of a mapping control circuit according to an embodiment.

FIGS. 4A to 4C are schematic diagrams of an operation of a mapping control circuit according to an embodiment.

FIGS. 5A to 5C are block diagrams of a mapping control circuit according to another embodiment.

FIGS. 6A to 6C are schematic diagrams of an operation of a mapping control circuit according to another embodiment.

### DETAILED DESCRIPTION OF DISCLOSED EMBODIMENTS

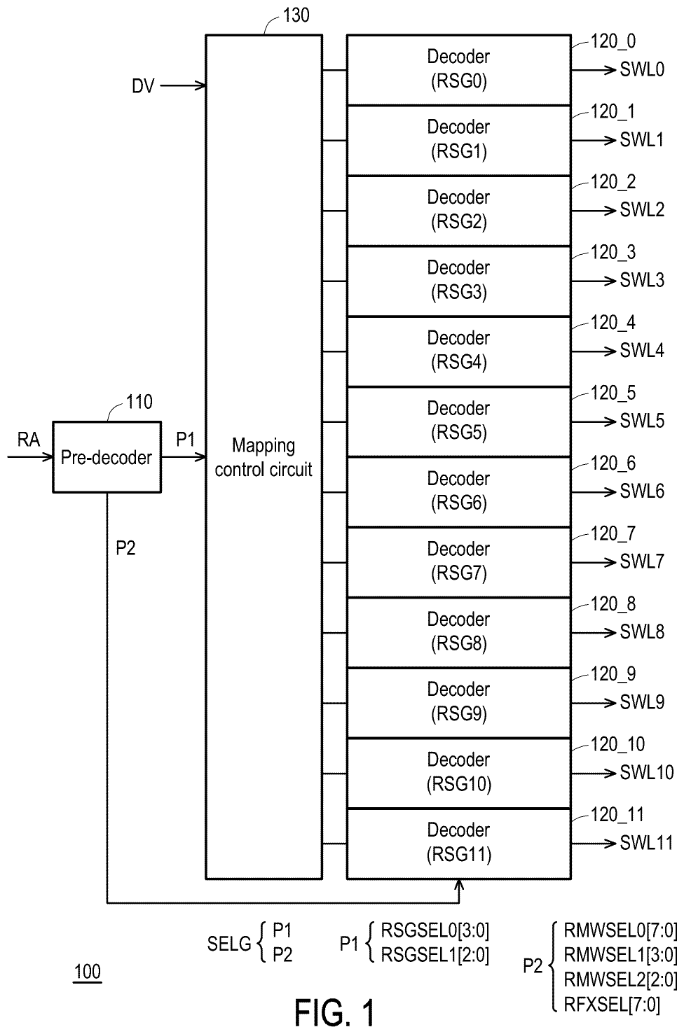

Referring to FIG. 1, a row decoder circuit 100 in this embodiment is, for example, adapted to memory devices compliant with standards such as hybrid memory cube (HMC), high bandwidth memory (HBM), double data rate (DDR), or low power double data rate (LPDDR).

The row decoder circuit 100 includes pre-decoder 110, decoders 120_0 to 120_11, and a mapping control circuit 130. The pre-decoder 110 may receive row address information RA of a memory cell to be accessed. The row address information RA may be formed by 13 bits, for example. The pre-decoder 110 may decode the row address information RA to provide a row select signal group SELG. A first portion P1 of the row select signal group SELG corresponds to a row address of a high bit portion, including a first row select signal RSGSEL0[3:0] and a second row select signal RSGSEL1[2:0]. A second portion P2 of the row select signal group SELG corresponds to a row address of a low bit portion, including row select signals RMWSEL0[7:0], RMWSEL1[3:0], RMWSEL2[2:0], and RFXSEL[7:0]. The pre-decoder 110 transmits the first portion P1 of the row select signal group SELG to the mapping control circuit 130, and transmits the second portion P2 of the row select signal group SELG to each of the decoders 120_0 to 120_11.

The decoders 120_0 to 120_11 sequentially corresponds to row address ranges RSG0 to RSG11. The row address ranges RSG0 to RSG11 represent initial default row address ranges of 12 memory blocks respectively opened by the decoders 120_0 to 120_11 in the memory device. For example, assuming that the total row address ranges provided by the above 12 memory blocks are 0 to 8191, the row address ranges RSG0 to RSG11 are shown in Table 1 below.

TABLE 1

| | |
|---|---|
| RSG0 | 0-687 |
| RSG1 | 688-1375 |
| RSG2 | 1376-2047 |
| RSG3 | 2048-2735 |
| RSG4 | 2736-3423 |
| RSG5 | 3424-4095 |
| RSG6 | 4096-4783 |
| RSG7 | 4784-5471 |
| RSG8 | 5472-6143 |
| RSG9 | 6144-6831 |
| RSG10 | 6832-7519 |
| RSG11 | 7250-8191 |

When none of the above 12 memory blocks are damaged (all available), the decoders 120_0 to 120_11 may respectively output word line signals SWL0 to SWL11 to the above 12 memory blocks to access the memory cells whose row addresses are in the row address ranges RSG0 to RSG11.

The mapping control circuit 130 is coupled to the pre-decoder 110 and the decoders 120_0 to 120_11. The mapping control circuit 130 may obtain a selected row address range according to the row select signal group SELG, and cause the decoder whose corresponding row address range is the same as the selected row address range in the decoders 120_0 to 120_11 to output a word line signal with an enable level (e.g., a high logic level).

Specifically, the mapping control circuit 130 may analyze and decode a signal of the first portion P1 of the row select signal group SELG to obtain the selected row address range where the memory cell to be accessed is located. At this time, the decoder whose corresponding row address range is the same as the selected row address range in the decoders 120_0 to 120_11 may output the corresponding word line signal according to the second portion P2 of the row select signal group SELG. Furthermore, when the selected row address range is equal to the row address range RSG0, the mapping control circuit 130 causes the decoder 120_0 to output the word line signal SWL0 with the enable level according to the second portion P2 of the row select signal group SELG. When the selected row address range is equal to the row address range RSG1, the mapping control circuit 130 causes the decoder 120_1 to output the word line signal SWL1 with the enable level according to the second portion P2 of the row select signal group SELG, and the rest may be derived by analogy.

In this embodiment, the mapping control circuit 130 may further receive verification data DV. The verification data DV is, for example, data obtained during a chip probing (CP) stage. The mapping control circuit 130 may learn a position of the damaged bad memory cell or bad memory block according to the verification data DV.

In addition, the mapping control circuit 130 may generate verification signals SDV0 to SDV11 according to multiple bit values forming the verification data DV. When one verification signal is at the high logic level (a logic value of 1), it indicates that the corresponding memory block is damaged because the bad memory cell may not be completely repaired. When one verification signal is at a low logic level (a logic value of 0), it indicates that the corresponding memory block may be completely repaired without the bad memory cell. Furthermore, when the verification signal SDV0 is at the high logic level (the logic value of 1), it indicates that the memory block opened by the decoder 120_0 is damaged, and when the verification signal SDV1 is at the high logic level (the logic value of 1), it indicates that the memory block opened by the decoder 120_1 is damaged. The rest may be derived by analogy.

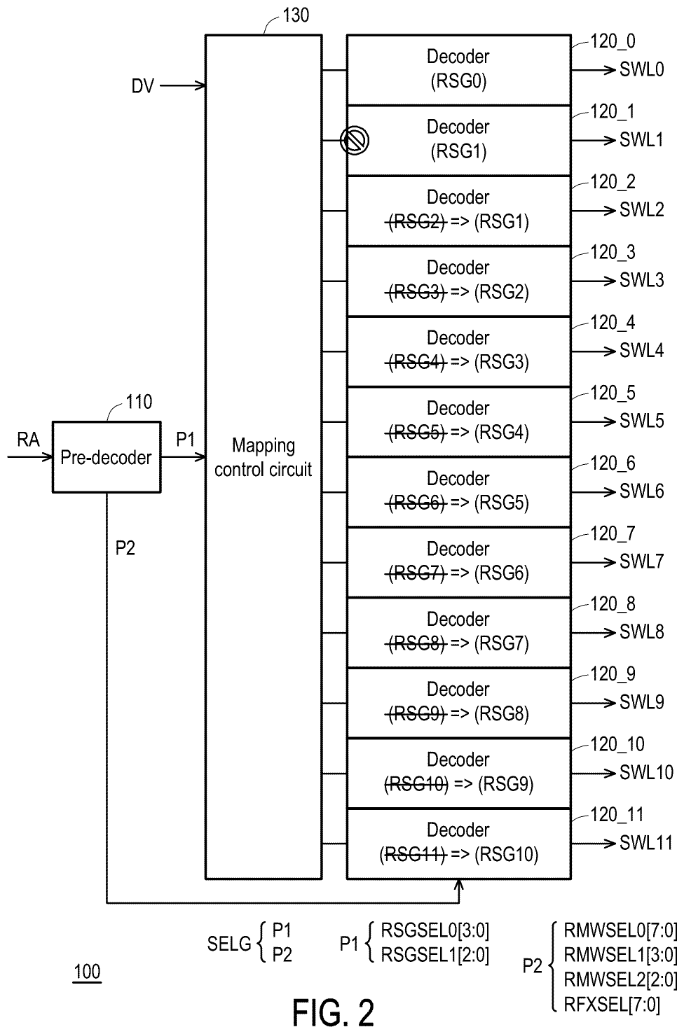

When there are damaged bad memory blocks among the 12 memory blocks opened by the decoders 120_0 to 120_11 respectively, the mapping control circuit 130 may reorder the row address ranges corresponding to the decoders 120_0 to 120_11 according to the verification data DV. For example, as shown in FIG. 2, when the memory block opened by the decoder 120_1 is a damaged bad memory block, the verification signal SDV1 is at the high logic level (the logic value of 1). Therefore, the mapping control circuit 130 may disable the decoder 120_1 as a bad memory block decoder according to the verification signal SDV1 with the high logic level.

At this time, in order to allow the memory device to be used normally, the mapping control circuit 130 may further shift the row address ranges corresponding to the decoders 120_2 to 120_11 that are ranked behind the decoder 120_1 as the bad memory block decoder from the row address ranges RSG2 to RSG11 forward to the row address ranges RSG1 to RSG10 according to the verification signals SDV0 to SDV11. In this way, the decoder 120_2 replaces the decoder 120_1 and corresponds to the row address range RSG1, so that the memory block opened by the decoder 120_1 may no longer be mapped.

Similarly, each of the decoders 120_3 to 120_11 will also replace the previous decoder and correspond to the row address range corresponding to the previous decoder.

In this way, the row decoder circuit 100 in this embodiment may skip the damaged bad memory blocks when performing mapping, thereby allowing the partially damaged memory device to still have availability.

It should be noted that although in this embodiment, the 12 decoders 120_0 to 120_11 that may open the 12 memory blocks are used for description, the disclosure is not limited thereto. Those skilled in the art may, based on the teachings of the disclosure, deduce the number of memory blocks and decoders to be less or more depending on actual requirements.

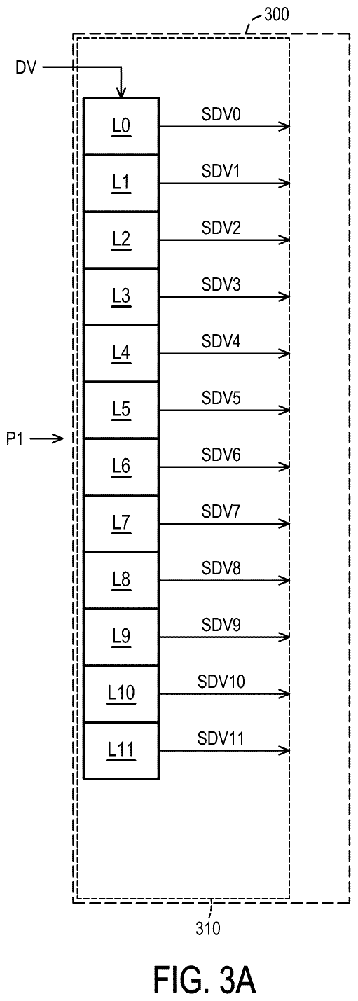

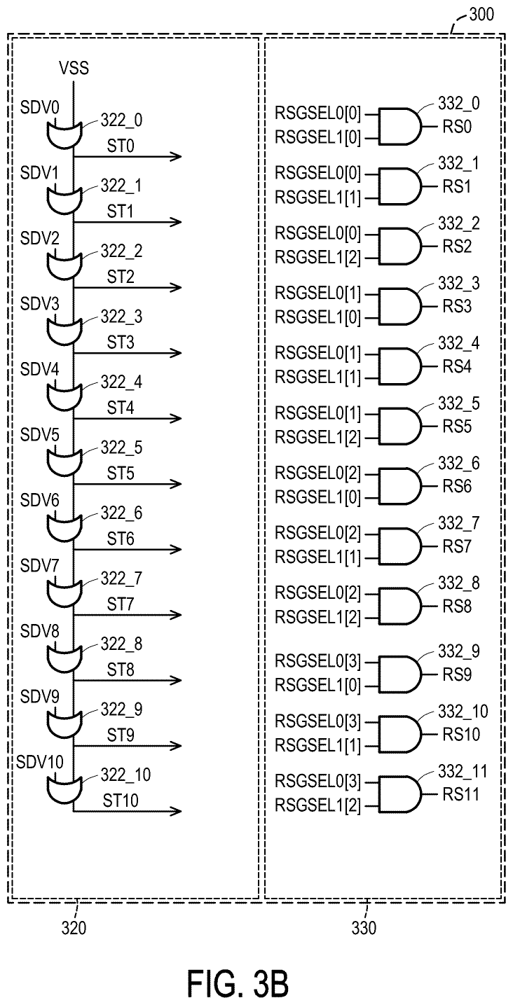

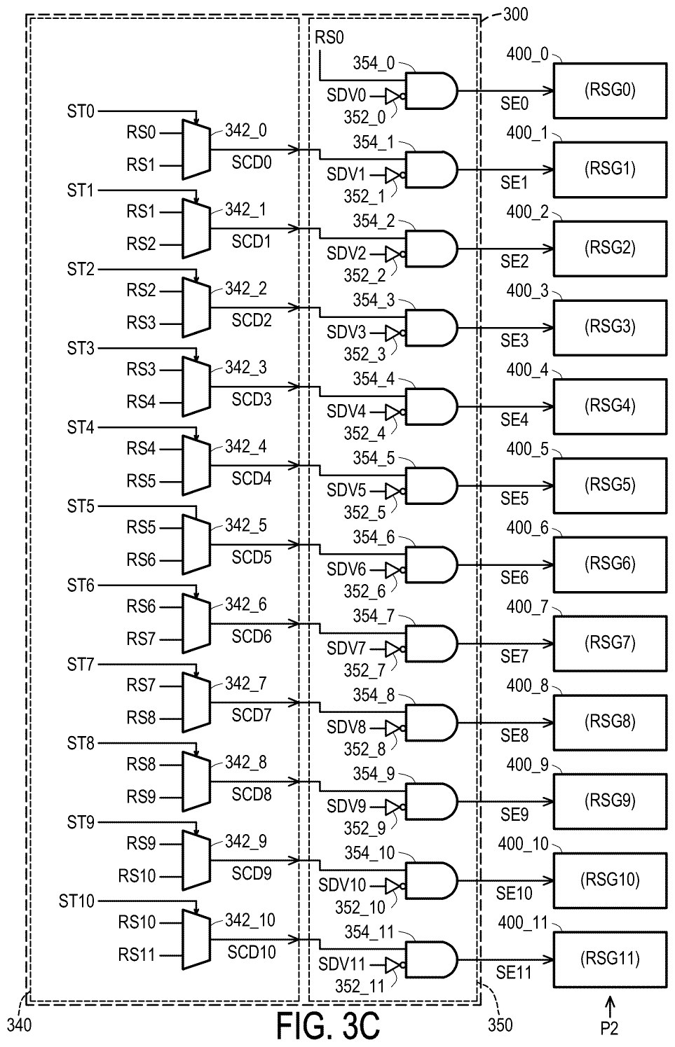

An embodiment is given below to describe the implementation of the mapping control circuit. A mapping control circuit 300 in this embodiment is adapted to a case where one memory block has damaged bad memory cells, and the row address ranges corresponding to decoders 400_0 to 400_11 are reordered. The mapping control circuit 300 includes a latch circuit 310, a first logic circuit 320, a second logic circuit 330, a multiplex circuit 340, and a third logic circuit 350. For clear description, internal structures of the latch circuit 310, the first logic circuit 320, the second logic circuit 330, the multiplex circuit 340, and the third logic circuit 350 in the mapping control circuit 300 are respectively shown in FIGS. 3A, 3B, and 3C.

Referring to FIGS. 3A, 3B, and 3C together, the latch circuit 310 may store the received verification data DV. When the system is powered on, the latch circuit 310 may, for example, obtain the verification data DV from another one-time programmable (OTP) memory. The latch circuit 310 includes latches L0 to L11. The latches L0 to L11 may sequentially store the bit values that form the verification data DV, and output them as the verification signals SDV0 to SDV11 respectively.

The first logic circuit 320 is coupled to the latch circuit 310. The first logic circuit 320 may receive the verification signals SDV0 to SDV10 and a low logic level signal VSS, and perform multi-level computation using the verification signals SDV0 to SDV10 and the low logic level signal VSS, so as to generate control signals ST0 to ST10.

In detail, in FIG. 3B, the first logic circuit 320 includes OR gates 322_0 to 322_10. The OR gates 322_0 to 322_10 are connected in series. First input ends of the OR gates 322_0 to 322_10 receive the verification signals SDV0 to SDV10 respectively. Output ends of the OR gates 322_0˜322_10 output the control signals ST0 to ST10 respectively. A second input end of a first-level OR gate (the OR gate 322_0) receives the low logic level signal VSS. Second input ends of the OR gates (the OR gate 322_1 to the OR gate 322_10) other than the first-level OR gate receives the control signal output by the output end of the OR gates of the previous level.

The second logic circuit 330 may receive the first portion P1 of the row select signal group SELG, and perform AND computation on the first row select signal RSGSEL0[3:0] in the first portion P1 and the second row select signal RSGSEL1[2:0] in the first portion P1, so as to generate computation signals RS0 to RS11.

The second logic circuit 330 includes AND gates 332_0 to 332_11. A first input end of each of the AND gates 332_0 to 332_11 receives a corresponding first row select signal in the first row select signal RSGSEL0[3:0]. A second input end of each of the AND gates 332_0 to 332_11 receives a corresponding second row select signal in the second row select signal RSGSEL1[2:0]. Output ends of the AND gates 332_0 to 332_11 respectively output the computation signals RS0 to RS11.

In FIG. 3C, the multiplex circuit 340 is coupled to the first logic circuit 320 and the second logic circuit 330. The multiplex circuit 340 receives the control signals ST0 to ST10 and the computation signals RS0 to RS11, and selects multiple of the computation signals RS0 to RS11 as decoding signals SCD0 to SCD10 according to the control signals ST0 to ST10.

In detail, the multiplex circuit 340 includes multiplexers 342_0 to 342_10. A first input end and a second input end of each of the multiplexers 342_0 to 342_10 receive two corresponding computation signals among the computation signals RS0 to RS11. For example, the first input end of the multiplexer 342_0 receives the computation signal RS0, and the second input end of the multiplexer 342_0 receives the computation signal RS1. The first input end of the multiplexer 342_1 receives the computation signal RS1, the second input end of the multiplexer 342_1 receives the computation signal RS2. The rest may be derived by analogy.

Control ends of the multiplexers 342_0 to 342_10 receive the control signals ST0 to ST10 respectively, and output ends of the multiplexers 342_0 to 342_10 output the decoding signals SCD0 to SCD10 respectively. Each of the multiplexers 342_0 to 342_10 selects one of the signal received by the first input end thereof (an upper input end) and the signal received by the second input end thereof (a lower input end) as the corresponding decoding signal and outputs it at the output end thereof according to the received control signal. Taking the multiplexer 342_1 as an example, when receiving the control signal ST1 with the high logic level, the multiplexer 342_1 will select the computation signal RS1 received by the first input end thereof (the upper input end) as the decoding signal SCD1 to be output. When receiving the control signal STI with the low logic level, the multiplexer 342_1 will select the computation signal RS2 received by the second input end thereof (the lower input end) as the decoding signal SCD1 to be output.

The third logic circuit 350 is coupled to the latch circuit 310, the second logic circuit 330, and the multiplex circuit 340. The third logic circuit 350 may receive the verification signals SDV0 to SDV11, the computation signal RS0 corresponding to the lowest address among the computation signals RS0 to RS11, and the decoding signals SCD0 to SCD10, and invert the verification signals SDV0 to SDV11 and then perform the AND computation on the computation signal RS0 and the decoding signals SCD0 to SCD10 respectively, so as to output generated enable signals SE0 to SE11 to the decoders 400_0 to 400_11 respectively.

Specifically, the third logic circuit 350 includes inverters 352_0 to 352_11 and AND gates 354_0 to 354_11. Input ends of the inverters 352_0 to 352_11 receive the verification signals SDV0 to SDV11 respectively.

A first input end of the AND gate 354_0 receives the computation signal RS0. First input ends of the AND gates 354_1 to 354_11 receive the decoding signals SCD0 to SCD10 respectively. Second input ends of the AND gates 354_0 to 354_11 are respectively coupled to output ends of the inverters 352_0 to 352_11. Output ends of the AND gates 354_0 to 354_11 respectively output the enable signals SE0 to SE11.

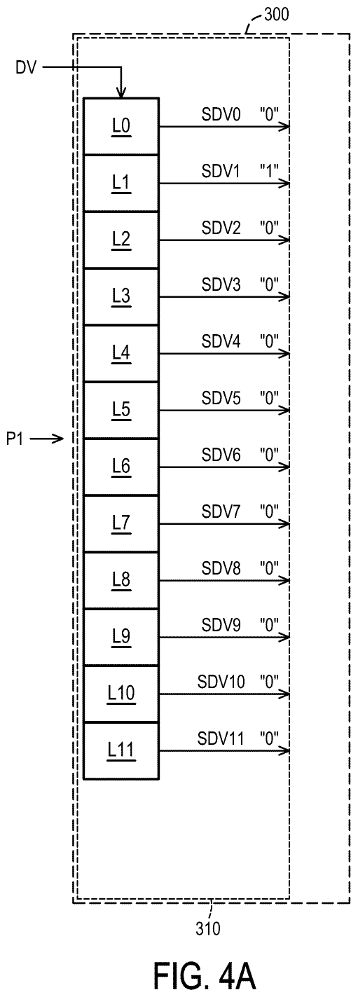

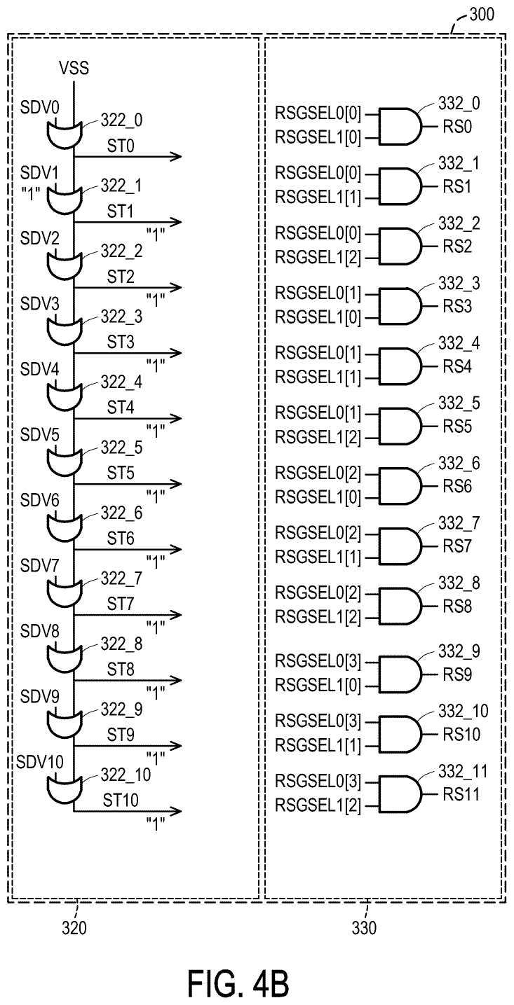

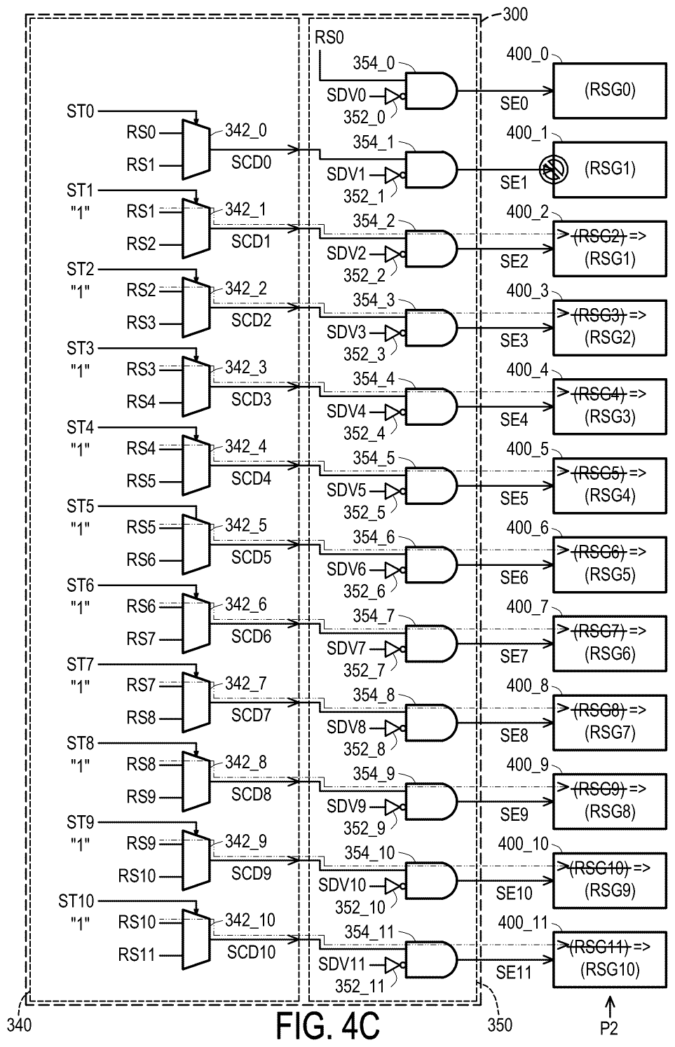

In an operation, for example, as shown in FIGS. 4A, 4B, and 4C, when there are damaged bad memory cells in the memory block opened by decoder 400_1, the inverter 352_1 in the third logic circuit 350 receives the verification signal SDV1 with the high logic level (the logic value of 1) from the latch L1 in the latch circuit 310. In this way, the AND gate 354_1 may only output the enable signal SE1 with the low logic level (the logic value of 0) to the decoder 400_1, thereby disabling the decoder 400_1 as a bad memory block decoder.

At this time, the OR gate 322_1 in the first logic circuit 320 will also receive the verification signal SDV1 with the high logic level. Since the OR gates 322_0 to 322_10 are connected in series, the control signals ST1 to ST10 output by the OR gates 322_1˜322_10 will all be adjusted to the high logic level. In this case, the multiplexers 342_1 to 342_10 in the multiplex circuit 340 will change to select the computation signals RS1 to RS10 received by the first input ends thereof (the upper input ends) as the decoding signals SCD1 to SCD10 to be output.

In this way, the row address ranges corresponding to the decoders 400_2 to 400_11 ranked behind the decoder 400_1 as the bad memory block decoder will be shifted forward from the row address ranges RSG2 to RSG11 to the row address ranges RSG1 to RSG10. In this way, the decoder 400_2 replaces the decoder 400_1 and corresponds to the row address range RSG1, so that the memory block opened by the decoder 400_1 may no longer be mapped.

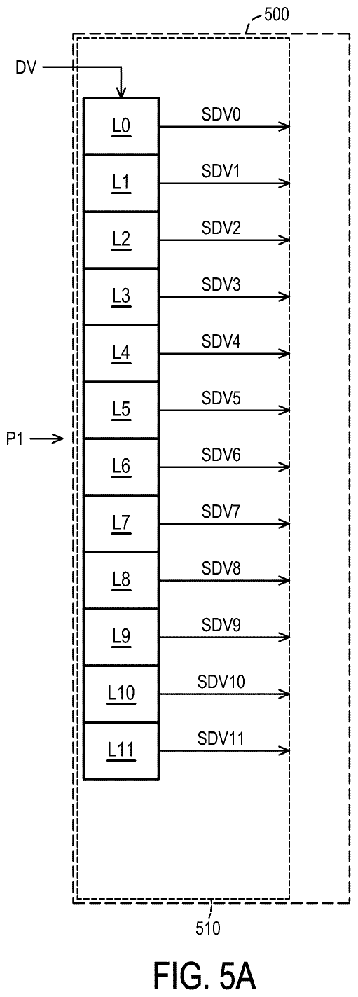

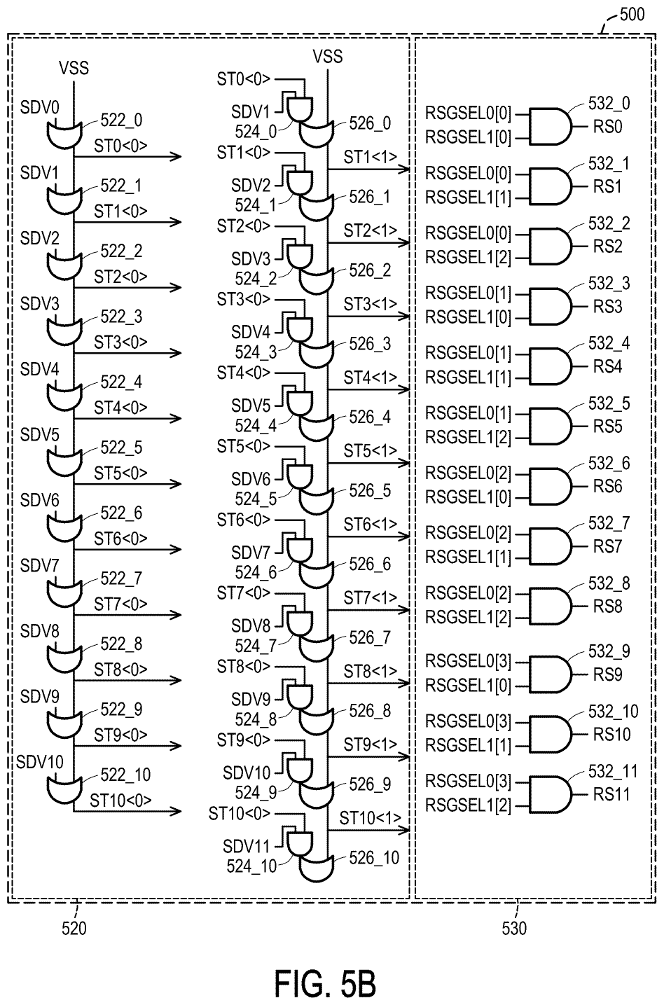

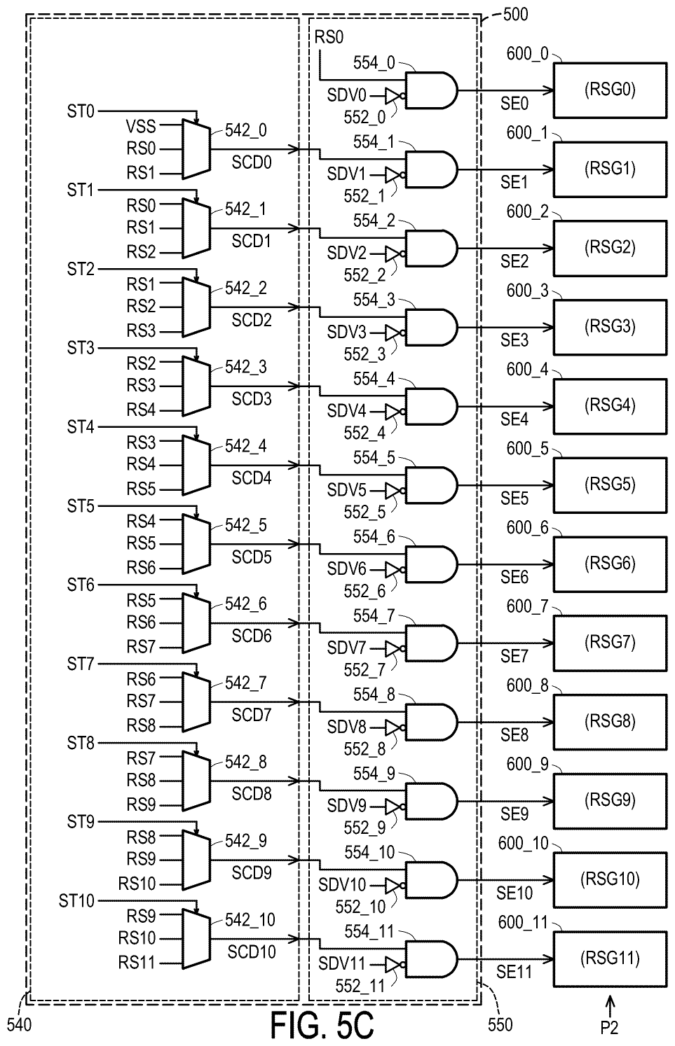

Another embodiment is given below to describe the implementation of the mapping control circuit. A mapping control circuit 500 in this embodiment is adapted to a case where one or two memory blocks are damaged, and row address ranges corresponding to decoders 600_0 to 600_11 are reordered. The mapping control circuit 500 includes a latch circuit 510, a first logic circuit 520, a second logic circuit 530, a multiplex circuit 540, and a third logic circuit 550. For clear description, internal structures of the latch circuit 510, the first logic circuit 520, the second logic circuit 530, the multiplex circuit 540, and the third logic circuit 550 in the mapping control circuit 500 are respectively shown in FIGS. 5A, 5B, and 5C.

Referring to FIGS. 5A, 5B, and 5C together, the latch circuit 510 may store the received verification data DV. The latches L0 to L11 included in the latch circuit 510 may sequentially store the bit values that form the verification data DV, and output them as the verification signals SDV0 to SDV11 respectively.

The first logic circuit 520 is coupled to the latch circuit 510. The first logic circuit 520 may receive the verification signals SDV0 to SDV10 and the low logic level signal VSS, and perform the multi-level computation using the verification signals SDV0 to SDV10 and the low logic level signal VSS, so as to generate the control signals ST0 to ST10. Different from the previous embodiment, in this embodiment, each of the control signals ST0 to ST10 is formed by two bit signals. For example, the control signal ST0 is formed by a bit signal ST0<0>and a bit signal ST0<1>, and the control signal ST1 is formed by a bit signal ST1<0>and a bit signal ST1<1>. The rest may be derived by analogy.

Specifically, in FIG. 5B, the first logic circuit 520 includes OR gates 522_0 to 522_10, AND gates 524_0 to 524_10, and OR gates 526_0 to 526_10. The OR gates 522_0 to 522_10 are connected in series. First input ends of the OR gates 522_0 to 522_10 receive the verification signals SDV0 to SDV10 respectively. Output ends of the OR gates 522_0 to 522_10 output bit signals ST0<0>to ST10<0>respectively. A second input end of the first-level OR gate (the OR gate 522_0) receives the low logic level signal VSS. The second input ends of the OR gates (the OR gate 522_1 to OR gate 522_10) other than the first-level OR gate receives the bit signal output by the output end of the OR gate of the previous level.

First input ends of the AND gates 524_0 to 524_10 receive the verification signals SDV1 to SDV11 respectively. Second input ends of the AND gates 524_0 to 524_10 receive the bit signals ST0<0>to ST10<0>respectively.

The OR gates 526_0 to 526_10 are connected in series. First input ends of the OR gates 526_0 to 526_10 are respectively coupled to output ends of the AND gates 524_0 to 524_10. Output ends of the OR gates 526_0 to 526_9 output bit signals ST1<1>to ST10<1>respectively. The second input end of the first-level OR gate (the OR gate 526_0) receives the low logic level signal VSS. The second input ends of the OR gates (the OR gate 526_1 to the OR gate 526_10) other than the first-level OR gate receives the bit signal output by the output end of the OR gate of the previous stage.

The second logic circuit 530 may receive the first portion P1 of the row select signal group SELG, and performs the AND computation on the first row select signal RSGSEL0[3:0] in the first portion P1 and the second row select signal RSGSEL1[2:0] in the first portion P1 through the AND gates 532_0 to 532_11, so as to generate the computation signals RS0 to RS11.

In FIG. 5C, the multiplex circuit 540 is coupled to the first logic circuit 520 and the second logic circuit 530. The multiplex circuit 540 receives the control signals ST0 to ST10 and the computation signals RS0 to RS11, and selects multiple of the computation signals RS0 to RS11 as the decoding signals SCD0 to SCD10 according to the control signals ST0 to ST10.

In detail, the multiplex circuit 540 includes multiplexers 542_0 to 542_10. Different from the previous embodiment, a first input end of the multiplexer 542_0 receives the low logic level signal VSS, and a second input end and a third input end of the multiplexer 542_0 receive the computation signals RS0 and RS1. A first input end, a second input end, and a third input end of each of the multiplexers 542_1 to 542_10 receive three corresponding computation signals among the computation signals RS0 to RS11. For example, the first input end of the multiplexer 542_1 receives the computation signal RS0, the second input end of the multiplexer 542_1 receives the computation signal RS1, and the third input end of the multiplexer 542_1 receives the computation signal RS2. The first input end of the multiplexer 542_2 receives the computation signal RS1, the second input end of the multiplexer 542_2 receives the computation signal RS2, the third input end of the multiplexer 542_2 receives the computation signal RS3. The rest may be derived by analogy.

Control ends of the multiplexers 542_0 to 542_10 receive the control signals ST0 to ST10 respectively, and output ends of the multiplexers 542_0 to 542_10 output the decoding signals SCD0 to SCD10 respectively. Each of the multiplexers 542_0 to 542_10 selects one of the signal received by the first input end thereof (the upper input end), the signal received by the second input end thereof (a middle input end), and the signal received by the third input end thereof (the lower input end) as the corresponding decoding signal and outputs it at the output end thereof according to the received control signal. Taking the multiplexer 542_1 as an example, when receiving the control signal ST1 (a logic value of 11) formed by the bit signal ST1<0>with the high logic level and the bit signal ST1<1>with the high logic level, the multiplexer 542_1 will select the computation signal RS0 received by the first input end thereof (the upper input end) as the decoding signal SCD1 to be output. When receiving the control signal ST1 (a logic value of 01) formed by the bit signal ST1<0>with the high logic level and the bit signal ST1<1>with the low logic level, the multiplexer 542_1 will select the computation signal RS1 received by the second input end thereof (the middle input end) as the decoding signal SCD1 to be output. When receiving the control signal ST1 (a logic value of 00) formed by the bit signal ST1<0>with the low logic level and the bit signal ST1<1>with the low logic level, the multiplexer 542_1 will select the computation signal RS2 received by the third input end thereof (the lower input end) as the decoding signal SCD1 to be output.

The third logic circuit 550 is coupled to the latch circuit 510, the second logic circuit 530, and the multiplex circuit 540. The third logic circuit 550 may receive the verification signals SDV0 to SDV11, the computation signal RS0 corresponding to the lowest address among the computation signals RS0 to RS11, and the decoding signals SCD0 to SCD10, and invert the verification signals SDV0 to SDV11 through the inverters 552_0 to 552_11 and then perform the AND computation on the computation signal RS0 and the decoding signals SCD0 to SCD10 through the AND gates 554_0 to 554_11 respectively, so as to output the generated enable signals SE0 to SE11 to the decoders 600_0 to 600_11 respectively.

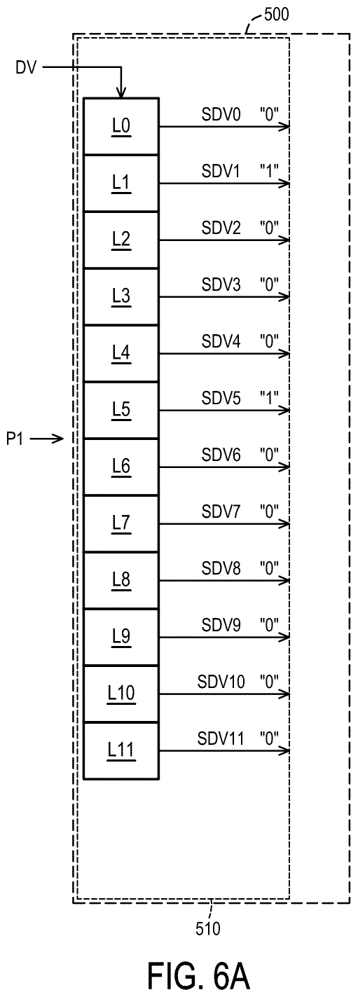

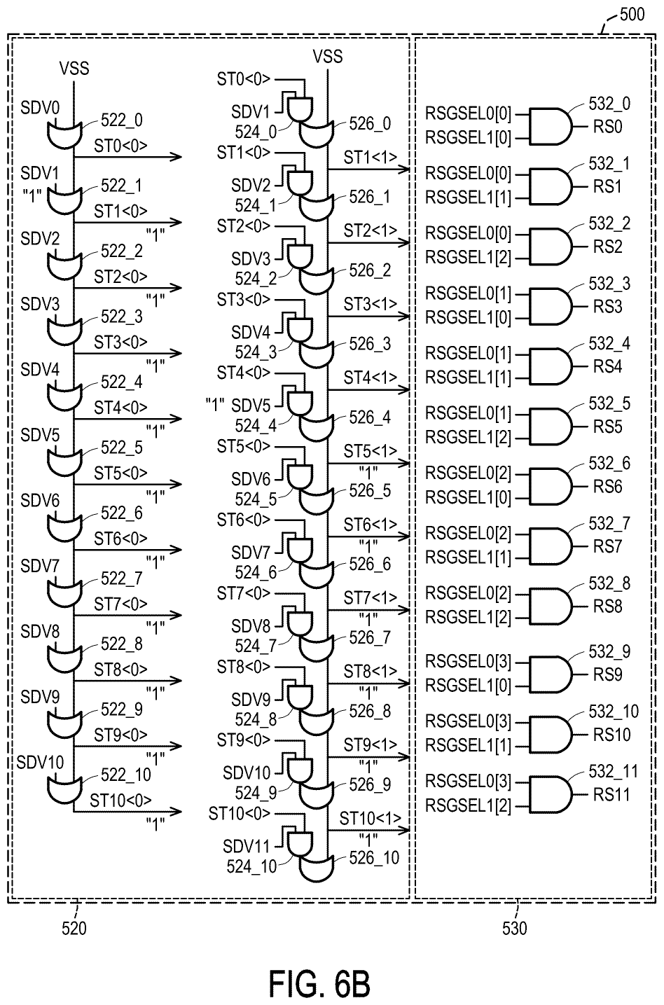

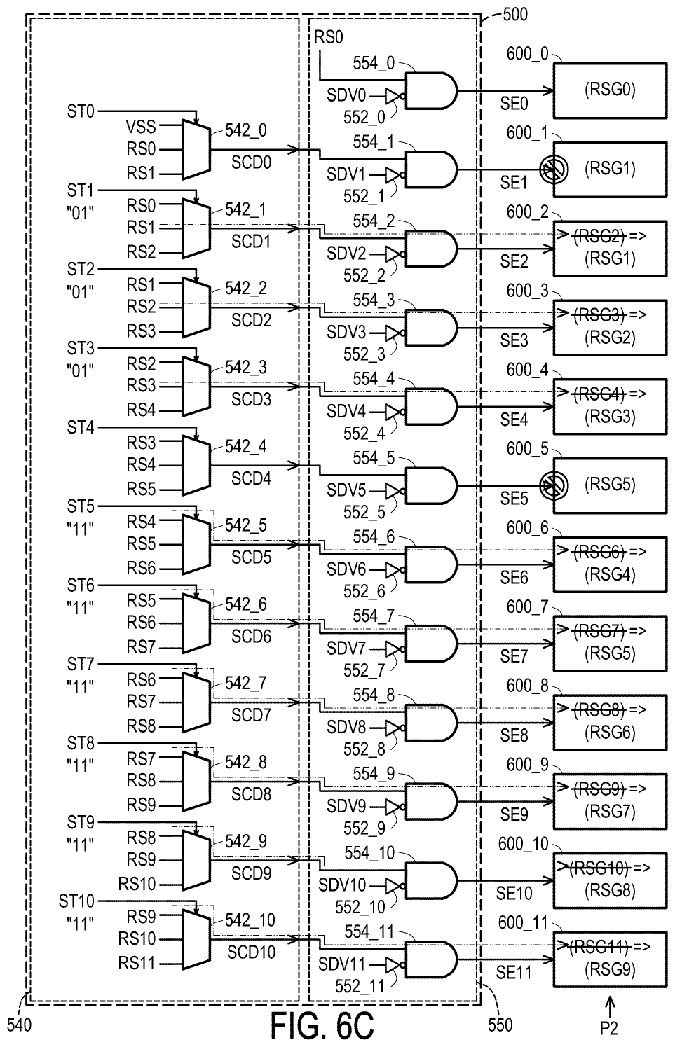

In the operation, for example, as shown in FIGS. 6A, 6B, and 6C, when there is damage in the two memory blocks opened by the decoders 600_1 and 600_5, the inverters 552_1 and 552_5 in the third logic circuit 550 will receive the verification signals SDV1 and SDV5 with the high logic level (the logic value of 1) from the latches L1 and L5 in the latch circuit 510 respectively. In this way, the AND gates 554_1 and 554_5 may only output the enable signals SE1 and SE5 with the low logic level (the logic value of 0) respectively to the decoders 600_1 and 600_5, thereby disabling the decoders 600_1 and 600_5 as bad memory block decoders.

At this time, the OR gate 522_1 in the first logic circuit 520 will also receive the verification signal SDV1 with the high logic level. Since the OR gates 522_0 to 522_10 are connected in series, the bit signals ST1<0>to ST10<0>output by the OR gates 522_1 to 522_10 will all be adjusted to the high logic level. In addition, output ends of the AND gates 524_1 to 524_10 that receive the bit signals ST1<0>to ST10<0>will be adjusted to the same logic level as the verification signals SDV2 to SDV11 respectively. In other words, the output end of the AND gate 524_4 will be adjusted to the same high logic level as the verification signal SDV5.

Since the OR gates 526_0 to 526_10 are also connected in series, the bit signals ST5<1>to ST10<1>output by the OR gates 526_4 to 526_9 will all be adjusted to the high logic level. In this case, a logic value of the control signals ST1 of ST3 is “01”, and a logic value of the control signal ST5 to ST10 is “11”. The multiplexers 542_1 to 542_3 in the multiplex circuit 540 will change to select the computation signals RS1 to RS3 received by the second input end thereof (the middle input end) as the decoding signals SCD1 to SCD3 to be output, and the multiplexers 542_5 to 542_10 will change to select the computation signals RS4 to RS9 received by the first input end thereof (the upper input end) as the decoding signals SCD5 to SCD10 to be output.

In this way, the row address ranges corresponding to the decoders 600_2 to 600_4 ranked behind the decoder 600_1 as the bad memory block decoder will be shifted forward from the row address ranges RSG2 to RSG4 to the row address ranges RSG1 to RSG3, and the row address ranges corresponding to the decoders 600_6 to 600_11 ranked behind the decoder 600_5 as the bad memory block decoder will be shifted forward from the row address ranges RSG6 to RSG11 to the row address ranges RSG4 to RSG9. In this way, the decoder 600_2 replaces the decoder 600_1 and corresponds to the row address range RSG1, and the decoder 600_7 replaces the decoder 600_5 and corresponds to the address range RSG5, so that the two memory blocks opened by the decoders 600_1 and 600_5 may no longer be mapped.

It should be noted that, for convenience of understanding, in the above embodiment, the case where one or two memory blocks have damaged bad memory cells is taken as an example for description, but the disclosure is not limited thereto. Those skilled in the art may adjust the internal structure of the mapping control circuit according to the actual requirements according to the teachings of the disclosure, so that it may be adapted to the case where more memory blocks have damaged bad memory cells.

Based on the above, the row decoder circuit in the disclosure does not perform conventional repair on the memory blocks having the bad memory cells, but reorders the row address ranges corresponding to the decoders. In this way, the damaged bad memory blocks may be skipped during mapping, and the memory device may be used normally, so that the partially damaged memory device may still have the availability, which may also increase a product yield and ease of use.

What is claimed is:

1. A row decoder circuit, adapted to a memory device, wherein the row decoder circuit comprises:
a pre-decoder configured to receive row address information and decode the row address information to provide a row select signal group;
a plurality of decoders sequentially corresponding to a plurality of row address ranges; and
a mapping control circuit coupled to the pre-decoder and the decoders, and configured to obtain a selected row address range according to the row select signal group and cause the decoder having the corresponding row address range that is the same as the selected row address range to output a word line signal,
wherein the mapping control circuit reorders the row address ranges corresponding to the decoders according to verification data.

2. The row decoder circuit according to claim 1, wherein the mapping control circuit obtains the selected row address range according to a first portion of the row select signal group, and the decoder having the corresponding row address range that is the same as the selected row address range outputs the corresponding word line signal according to a second portion of the row select signal group.

3. The row decoder circuit according to claim 1, wherein the mapping control circuit generates a plurality of verification signals according to the verification data, and disables at least one bad memory block decoder in the decoders according to the verification signals.

4. The row decoder circuit according to claim 3, wherein the mapping control circuit shifts forward the row address scopes corresponding to the decoders ranked behind the at least one bad memory block decoder according to the verification signals, thereby replacing the at least one bad memory block decoder.

5. The row decoder circuit according to claim 1, wherein the mapping control circuit comprises:
a latch circuit configured to store the verification data, wherein the latch circuit comprises a plurality of latches, and the latches output a plurality of bit values forming the verification data as a plurality of verification signals respectively.

6. The row decoder circuit according to claim 5, wherein the mapping control circuit further comprises:
a first logic circuit coupled to the latch circuit, configured to receive the verification signals and a low logic level signal, and perform multi-level computation using the verification signals and the low logic level signal to generate a plurality of control signals.

7. The row decoder circuit according to claim 6, wherein the first logic circuit comprises:
a plurality of OR gates connected in series, wherein a first input end of each of the OR gates receives the corresponding verification signal, an output end of each of the OR gates outputs the corresponding control signal, a second input end of a first-level OR gate receives the low logic level signal, and second input ends of the OR gates other than the first-level OR gate receive the control signal output by the output end of the OR-gate of a previous level.

8. The row decoder circuit according to claim 6, wherein each of the control signals comprises a first bit signal and a second bit signal, and the first logic circuit comprises:
a plurality of first OR gates connected in series, wherein a first input end of each of the first OR gates receives the corresponding verification signal, an output end of each of the first OR gates outputs the corresponding first bit signal, a second input end of a first-level first OR gate receives the low logic level signal, and second input ends of the first OR gates other than the first-level first OR gate receive the first bit signal output by the output end of the first OR gate of a previous level;
a plurality of AND gates, wherein a first input end of each of the AND gates receives the corresponding verification signal, and a second input end of each of the AND gates receives the corresponding first bit signal; and
a plurality of second OR gates connected in series, wherein a first input end of each of the second OR gates is coupled to an output end of the corresponding AND gate, an output end of each of the second OR gates outputs the corresponding second bit signal, a second input end of a first-level second OR gate receives the low logic level signal, and second input ends of the second OR gates other than the first-level second OR gate receive the second bit signal output by the output end of the second OR gate of a previous stage.

9. The row decoder circuit according to claim 6, wherein the mapping control circuit further comprises:
a second logic circuit configured to receive a first portion of the row select signal group and perform AND computation on a plurality of first row select signals in the first portion and a plurality of second row select signals in the first portion to generate a plurality of computation signals.

10. The row decoder circuit according to claim 9, wherein the second logic circuit comprises:
a plurality of AND gates, wherein a first input end of each of the AND gates receives the corresponding first row select signal, a second input end of each of the AND gates receives the corresponding second row select signal, and output ends of the AND gates output the corresponding computation signals.

11. The row decoder circuit according to claim 9, wherein the mapping control circuit further comprises:
a multiplex circuit coupled to the first logic circuit and the second logic circuit, configured to receive the control signals and the computation signals, and select a plurality of the computation signals as a plurality of decoding signals according to the control signals.

12. The row decoder circuit according to claim 11, wherein the multiplex circuit comprises:
a plurality of multiplexers, wherein a first input end and a second input end of each of the multiplexers receive the two corresponding computation signals, and a control end of each of the multiplexers receives the corresponding control signal, and accordingly selects one of the signal received by the first input end thereof and the signal received by the second input end thereof as the corresponding decoding signal to be output at an output end thereof.

13. The row decoder circuit according to claim 11, wherein the multiplex circuit comprises:
a plurality of multiplexers, wherein a first input end of one of the multiplexers receives the low logic level signal, a second input end and a third input end of the one of the multiplexers receive the two corresponding computation signals, a first input end, a second input end, and a third input end of each of the other multiplexers receive the three corresponding computation signals, and a control end of each of the multiplexers receives the corresponding control signal, and accordingly selects the signal received by the first input end thereof, the signal received by the second input end thereof, and the signal received by the third input end thereof as the corresponding decoding signal to be output at an output end thereof.

14. The row decoder circuit according to claim 11, wherein the mapping control circuit further comprises:
a third logic circuit coupled to the latch circuit, the second logic circuit, and the multiplex circuit, configured to receive the verification signals, the computation signal corresponding to a lowest address among the computation signals, and the decoding signals, invert the verification signals and then perform the AND computation on the operation signal corresponding to the lowest address and the decoding signals respectively, so as to output generated enable signals to the decoders respectively.

15. The row decoder circuit according to claim 14, wherein the third logic circuit comprises:
a plurality of inverters, wherein an input end of each of the inverters receives the corresponding verification signal; and
a plurality of AND gates, wherein a first input end of one of the AND gates receives the computation signal corresponding to the lowest address among the computation signals, a first input end of each of the other AND gates receives the corresponding decoding signal, a second input end of each of the AND gates is coupled to an output end of the corresponding inverter, and an output end of each of the AND gates outputs the corresponding enable signal.

16. The row decoder circuit according to claim 1, wherein the mapping control circuit learns a position of at least one damaged bad memory block according to the verification data.
